(19) United States
(12) Patent Application Publication
(10) Pub. No.: US 2025/0113697 A1
(43) Pub. Date: Apr. 3, 2025

(54) MICRO-LED DISPLAY CHIP AND METHOD FOR MANUFACTURING THE SAME

(71) Applicant: Raysolve Optoelectronics (Suzhou) Company Limited, Suzhou (CN)

(72) Inventor: Wing Cheung CHONG, Suzhou (CN)

(73) Assignee: Raysolve Optoelectronics (Suzhou) Company Limited, Suzhou (CN)

(21) Appl. No.: 18/981,134

(22) Filed: Dec. 13, 2024

Related U.S. Application Data
(63) Continuation of application No. PCT/CN2023/098893, filed on Jun. 7, 2023.

(30) Foreign Application Priority Data
Jun. 15, 2022 (CN) 202210675860.X

(51) Int. Cl. H10H 29/85; H10H 29/01; H10H 29/80

(52) U.S. Cl. CPC H10H 29/857; H10H 29/0364; H10H 29/942

(57) ABSTRACT

A Micro-LED display chip and a method for manufacturing the same are provided according to the present application. The method includes: providing a driving substrate; providing a first LED layer; bonding the first LED layer to the driving substrate, where the first LED units and a first conductive column are electrically connected to contacts respectively; disposing a second LED layer on the first LED layer, where the second LED layer consists of multiple second LED units and a second filling structure located between the second LED units, the second LED units are electrically connected to the first conductive column directly below them, and the second LED units emit light of a different color from that of the first LED units. This facilitates reducing the process difficulty in manufacturing the multicolor Micro-LED display chips.

### CROSS-REFERENCE TO RELATED APPLICATIONS

This application claims the priority of the PCT Application No. PCT/CN2023/098893 filed on Jun. 7, 2023, and this PCT Application claims the priority of the Chinese Patent Application No. 202210675860.X, titled “MICRO-LED DISPLAY CHIP AND METHOD FOR MANUFACTURING THE SAME”, filed on Jun. 15, 2022 with the China National Intellectual Property Administration, which is incorporated herein by reference in its entirety.

### TECHNICAL FIELD

The present disclosure relates to the technical field of semiconductor electronic devices, and in particular to a Micro-LED display chip and a method for manufacturing the same.

### BACKGROUND

The emergence of Micro-LED display technology has enabled a display device to be made into a miniaturized and high-resolution display device such as an Augmented Reality (AR) display device, a Near-eye display (NED) device, and a wearable display device. Micro-LED has significant market potential with its advantages of small size, high brightness, fast response, and long lifespan.

Currently, a full-color Micro-LED display chip typically integrates a wavelength conversion layer onto a monochrome display chip. This approach uses the RGB three primary colors required for full-color display. However, the LED array in the Micro-LED display is densely integrated, with distances of LED pixel points in the order of 0.1˜100 micrometers. As the size of the pixel point in the Micro-LED display chip decreases, the difficulty of fabricating the wavelength conversion layer increases, significantly complicating the production of the full-color Micro-LED display chip.

### SUMMARY

In view of this, a Micro-LED display chip and its manufacturing are provided according to various embodiments of the present disclosure, realizing a multi-color or full-color display of the Micro-LED display chip, helping reduce the difficulty in manufacturing the multi-color or full-color Micro-LED display chip, and to a certain extent, avoiding the damage on the driving substrate during the manufacturing process, thus increasing the yield rate, and lowering the production cost.

A method for manufacturing a Micro-LED display chip is provided according to an embodiment of the present disclosure. The method includes the following steps: providing a driving substrate, where the driving substrate includes a driving circuit and a contact electrically connected to the driving circuit; providing a first LED layer, where the first LED layer consists of multiple first LED units, a first filling structure located between the first LED units, and a first conductive column passing through the first filling structure; bonding the first LED layer to the driving substrate, where the first LED units and the first conductive column are electrically connected to the contacts, respectively; disposing a second LED layer on the first LED layer, where the second LED layer consists of multiple second LED units and a second filling structure located between the second LED units, the second LED unit is electrically connected to the first conductive column directly below it, and the second LED units emit light of a different color from that of the first LED units.

A Micro-LED display chip is provided according to an embodiment of the present disclosure, including: a driving substrate, where the driving substrate includes a driving circuit and a contact electrically connected to the driving circuit; a first LED layer disposed on the driving substrate, where the first LED layer includes multiple first LED units, a first filling structure disposed between the first LED units, and a first conductive column passing through the first filling structure, and the first LED units and the first conductive column are electrically connected to the contacts respectively; and a second LED layer disposed on the first LED layer, where the second LED layer includes multiple second LED units and a second filling structure located between the second LED units, the second LED units are electrically connected to the first conductive column directly below them, and the second LED units emit light of a different color from that of the first LED units.

A display panel is provided according to an embodiment of the present disclosure, including the Micro-LED display chip of any one of the above embodiments.

A display device is provided according to an embodiment of the present disclosure, including the Micro-LED display chip described in any one of the above embodiments.

The method for manufacturing the Micro-LED display chip is provided according to the embodiment of the present disclosure. By providing the first filling structure between the multiple first LED units of the first LED layer, and disposing the first conductive column passing through the first filling structure between the fillings, where the first LED units and the first conductive column are electrically connected to the driving circuit through the contacts, as well as by providing multiple second LED units on the first LED layer and the second filling structure disposed between the second LED units, where the second LED units are electrically connected to the first conductive column directly below them, and with the second LED units emitting light of a different color from that of the first LED units, a colorful display is realized. Since the LED display chip may realize a multi-color display without a wavelength conversion layer, the difficulty of manufacturing the LED chip is reduced to a certain extent.

Also, by forming the first LED layer and the second LED layer respectively, and then connecting the first LED layer and the second LED layer to the driving substrate in turn, the driving substrate is realized to drive and control the first LED unit and the second LED unit individually, which reduces the number of times that the driving substrate involves in the process and helps to protect the driving substrate, and to a certain extent avoids the damage on the driving substrate during the manufacturing process, thereby to a certain extent, the yield rate of the Micro-LED display chip is improved and the cost is reduced.

### BRIEF DESCRIPTION OF DRAWINGS

FIG. 1 is a schematic structural view of a driving substrate provided according to an embodiment.

FIG. 2a to FIG. 2m are schematic structural views showing a method for manufacturing a Micro-LED display chip provided according to an embodiment in different manufacturing stages.

FIG. 3a to FIG. 3h are schematic structural views showing a method for manufacturing a Micro-LED display chip provided according to an embodiment in different manufacturing stages.

FIG. 4 is a schematic structural view of a second LED layer provided according to an embodiment.

FIG. 5 is a schematic structural view of a third LED layer provided according to an embodiment.

FIG. 6 is a schematic structural view of a Micro-LED display chip provided according to an embodiment.

FIG. 7 is a schematic structural view of a Micro-LED display chip provided according to an embodiment.

FIG. 8 is a schematic structural view of a Micro-LED display chip provided according to an embodiment.

FIG. 9 is a schematic structural view of a Micro-LED display chip provided according to an embodiment.

### DETAILED DESCRIPTION OF THE EMBODIMENTS

Technical solutions in the embodiments of the present disclosure are clearly and completely described below in accompany with the drawings of the embodiments of the present disclosure. Apparently, the described embodiments are only part of the embodiments of the present disclosure, rather than all of the embodiments. All other embodiments obtained by those skilled in the art based on the embodiments in the present disclosure without any creative efforts fall within the protection scope of the present disclosure.

A method for manufacturing a micro-LED display chip is provided according to an embodiment of the present disclosure. The method for manufacturing the micro-LED display chip may include the following steps.

Step S110: providing a driving substrate 300, where the driving substrate 300 includes a driving circuit and a contact electrically connected to the driving circuit.

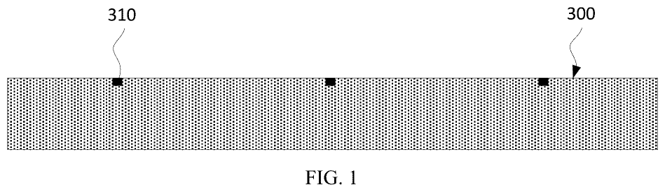

With reference to FIG. 1, in some embodiments, the driving substrate 300 may be made of semiconductor material. The semiconductor material may be at least one of silicon, silicon carbide, gallium nitride, germanium, gallium arsenide, indium phosphide, and other materials. The driving substrate 300 may be made of non-conductive material such as glass, plastic, or sapphire wafer. The driving substrate 300 may be a CMOS substrate, and may also be a TFT substrate. The driving substrate 300 may include a driving circuit, which is not shown in FIG. 1. The driving circuit is used to provide an electrical signal to an LED unit and to control brightness of the LED unit through the electrical signal. It is understood that the LED unit may refer to one or more of a first LED unit 210, a second LED unit 410, and a third LED unit 510.

With reference to FIG. 1, in some embodiments, the driving substrate 300 includes a contact 310. There may be multiple contacts 310, which may be spaced apart from each other. The contacts 310 may be made of at least one of Cu, Ag, Au, Al, W, Mo, Ni, Ti, Pt, Pd, and other materials. The contacts 310 may be connected to the driving circuit and the LED unit, respectively, allowing the driving circuit to be electrically connected to the LED unit, and enabling the driving circuit to drive the LED unit to emit light. The contacts 310 may be disposed on a surface of the substrate, facilitating the electrical connection between the driving circuit and the LED unit.

Step S120: providing a first LED layer 200, where the first LED layer 200 includes multiple first LED units 210, a first filling structure 220 disposed between the first LED units 210, and a first conductive column 221 passing through the first filling structure 220.

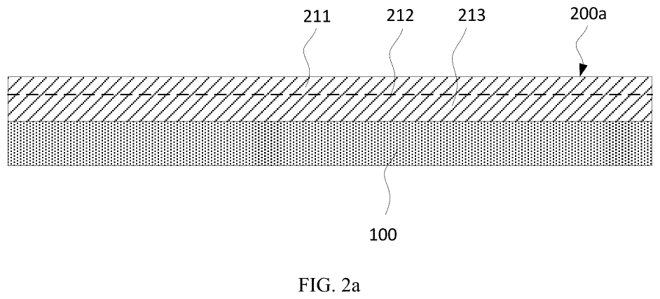

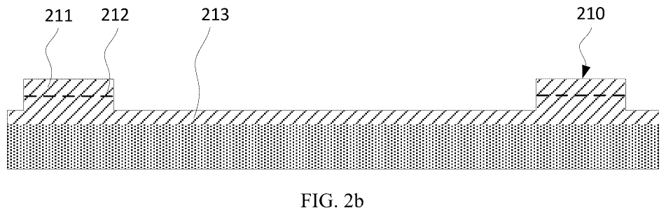

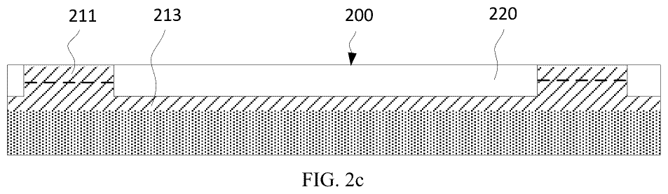

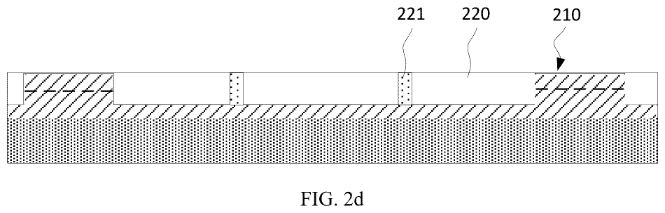

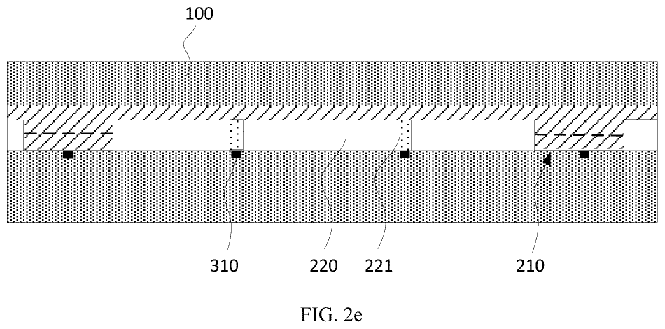

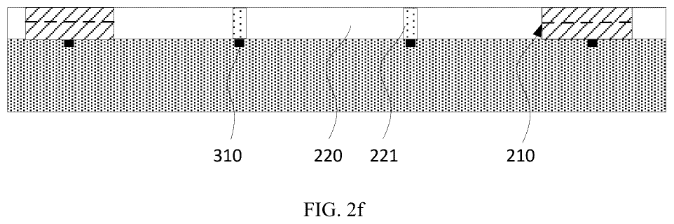

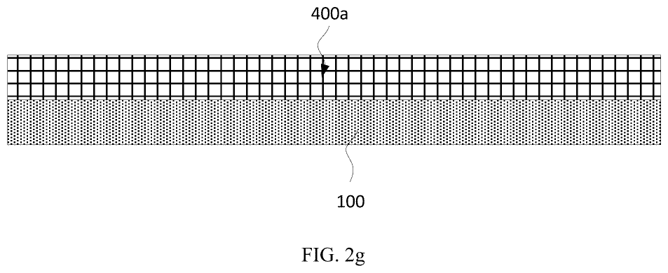

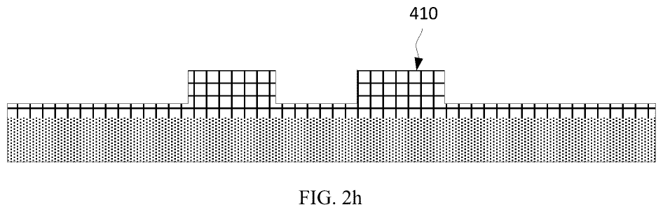

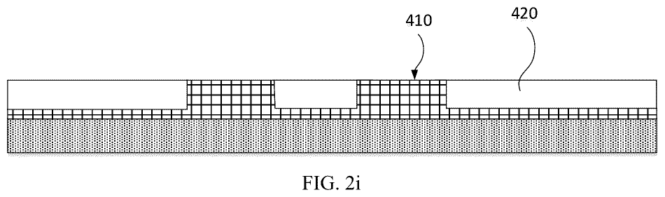

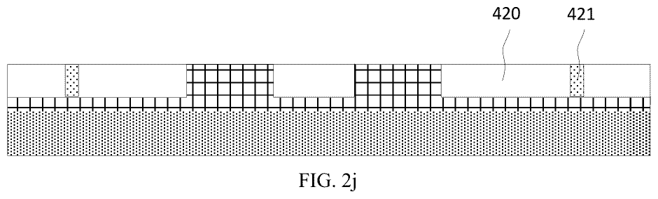

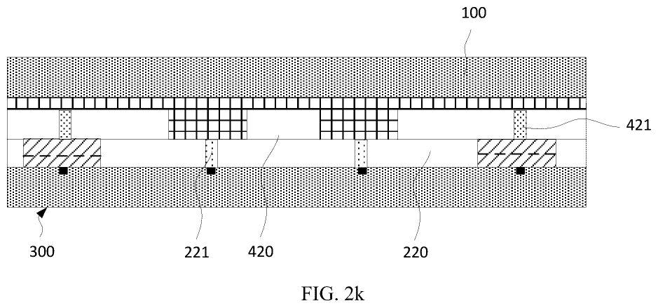

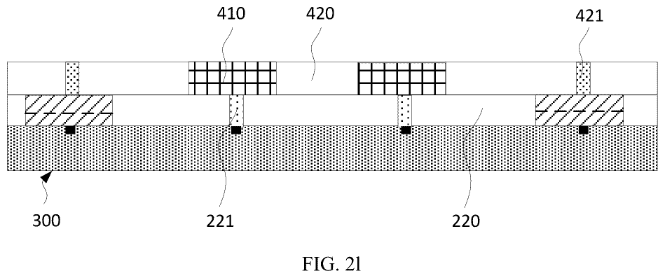

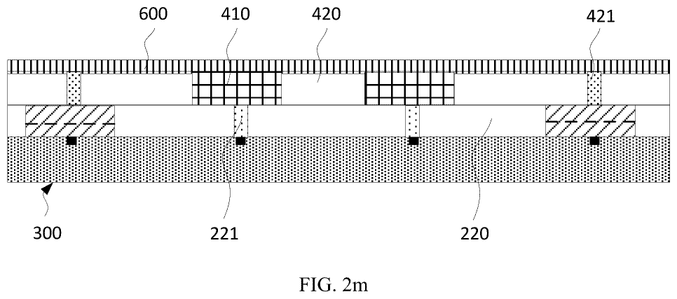

With reference to FIG. 2a, in some embodiments, the first LED unit 210 is formed by processing a first LED epitaxial layer 200a including a first doped semiconductor layer 211, an active layer 212, and a second doped semiconductor layer 213. The first LED unit 210 may be formed by removing the first doped semiconductor layer 211, the active layer 212, and part of the thickness of the second doped semiconductor layer 213 in certain regions of the first LED epitaxial layer 200a.

In some embodiments, the material of the first doped semiconductor layer 211 and the second doped semiconductor layer 213 may be II-VI material or III-V nitride material. Specifically, for example, the first doped semiconductor layer 211 and the second doped semiconductor layer 213 may be a one-layer or multilayer semiconductor structure composed of one or more materials selected from ZnSe, ZnO, GaN, AIN, InN, InGaN, GaP, AlInGaP, or AlGaAs, respectively. The active layer 212 may have one of a single quantum well structure, a multiple quantum well (MQW) structure, or a stacked structure of a quantum well and barrier layer. The active layer 212 is positioned between the first doped semiconductor layer 211 and the second doped semiconductor layer 213. Holes and electrons are excited in the active layer 212 with a specific wavelength of light.

In some embodiments, the first doped semiconductor layer 211 may be a P-type semiconductor layer and the second doped semiconductor layer 213 may be an N-type semiconductor layer. The first doped semiconductor layer 211 and the second doped semiconductor layer 213 may be electrically connected to the contact 310 and a common electrode 600, respectively, and the common electrode 600 may be a cathode. The contact 310 may be electrically connected to the first doped semiconductor layer 211 via an anode. In some embodiments, the first doped semiconductor layer 211 may also be an N-type semiconductor layer, and accordingly, the second doped semiconductor layer 213 is a P-type semiconductor layer.

With reference to FIG. 2a, in some embodiments, the first LED epitaxial layer 200a may include the first doped semiconductor layer 211, the active layer 212, and the second doped semiconductor layer 213. The first LED epitaxial layer 200a may be formed by growing on the substrate 100. The substrate 100 may be one of a sapphire, Si, GaAs, InP, GaN, AlN, SiC substrate, or the like.

In some embodiments, the first LED layer 200 includes multiple first LED units 210, which are capable of being independently driven. The first LED unit 210 includes the first doped semiconductor layer 211, the active layer 212, and the second doped semiconductor layer 213. The first doped semiconductor layer 211 may be used to electrically connect to the contact 310, and the second doped semiconductor layer 213 may be used to electrically connect to the common electrode 600.

In some embodiments, a conductive layer may be formed on the first doped semiconductor layer 211 of the first LED unit 210. The conductive layer may be made of metallic material, such as indium tin oxide. The first LED unit 210 is electrically connected to the contact via the conductive layer on the first doped semiconductor layer 211.

With reference to FIG. 2a and FIG. 2b, in some embodiments, the step of providing the first LED layer includes providing the first LED epitaxial layer 200a, and etching the first LED epitaxial layer 200a to form multiple first LED units 210, where each of the first LED units 210 includes the first doped semiconductor layer 211, the active layer 212 and the second doped semiconductor layer 213, and the second doped semiconductor layer 213 of the adjacent first LED units 210 are connected to each other. It may be understood that the first LED epitaxial layer 200a includes the first doped semiconductor layer 211, the active layer 212, and the second doped semiconductor layer 213. The first doped semiconductor layer 211, the active layer 212, and part of the thickness of the second doped semiconductor layer 213 in certain regions are removed to form multiple first LED units 210. In these regions, the first doped semiconductor layer 211 and the active layer 212 are completely removed, while part of the second doped semiconductor layer 213 is retained. Accordingly, the multiple first LED units 210 are formed, with the first LED units 210 interconnected through the second doped semiconductor layer 213. Two first LED units 210 interconnected through the second doped semiconductor layer 213 are illustrated in FIG. 2b. The removal of certain regions of the first LED epitaxial layer 200a may be achieved through an etching process. Specifically, the etching process may refer to dry etching, or wet etching.

In some embodiments, the step of providing the first LED layer 200 includes providing the first LED epitaxial layer 200a, and etching the first LED epitaxial layer 200a to form multiple first LED units 210 that are spaced apart from each other, where each of the first LED units 210 includes the first doped semiconductor layer 211, the active layer 212, and the second doped semiconductor layer 213. Specifically, the first LED epitaxial layer 200a may be provided, which includes the first doped semiconductor layer 211, the active layer 212, and the second doped semiconductor layer 213. By removing part of the first LED epitaxial layer 200a, multiple first LED units 210 spaced apart from each other are formed. In this case, part of the first LED epitaxial layer 200a is removed, and correspondingly, remaining parts of the first LED epitaxial layer 200a form multiple first LED units 210. The multiple first LED units 210 are spatially spaced apart from each other, resulting in a structure of the multiple spaced-apart first LED units 210.

In some embodiments, the first LED units 210 are independent from each other. Since the first LED units 210 are formed by removing part or all of the thickness of certain regions of the first LED epitaxial layer 200a, there is no remaining part of the first LED epitaxial layer 200a between the multiple first LED units 210, or only part of the thickness of the first LED epitaxial layer 200a of the first LED unit 210 is retained. As a result, an uneven surface is formed between the multiple first LED units 210.

With reference to FIG. 2c, in some embodiments, the step of providing the first LED layer includes providing the first filling structure 220 between the first LED units 210. The first LED layer 200 includes the first filling structure 220 that enables the multiple first LED units 210 to have a first flattened surface. By providing the first filling structure 220, the unevenness of the surface formed by the multiple first LED units 210 is reduced. By providing the first filling structure 220, it is possible to make the thicknesses of the first LED layer 200 in various regions tend to be the same, thereby forming the first flattened surface.

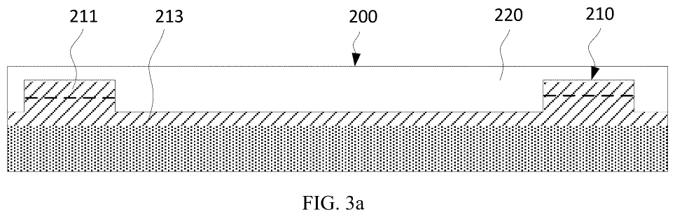

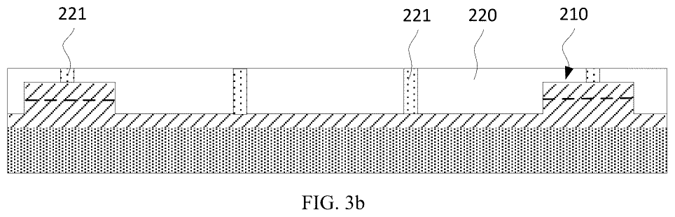

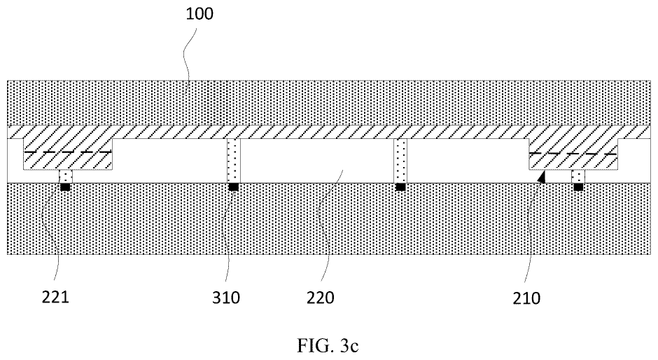

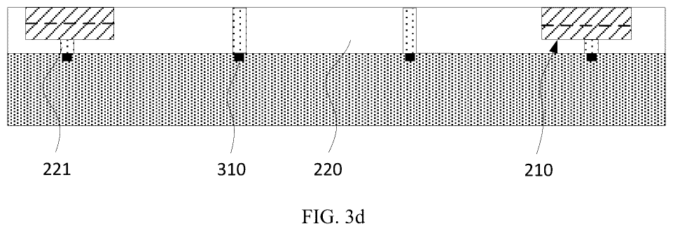

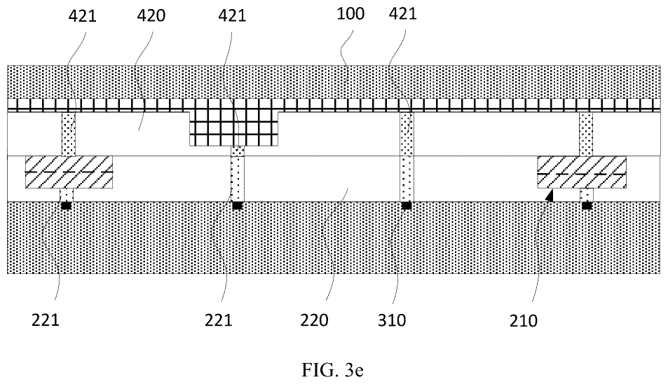

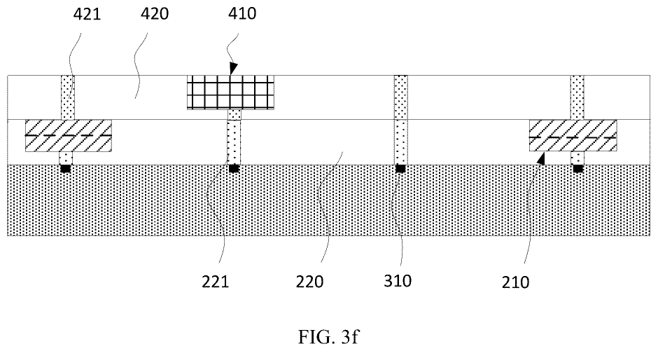

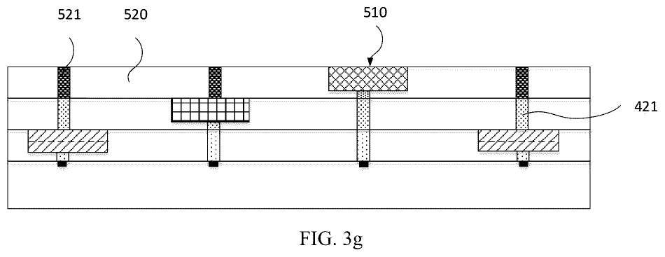

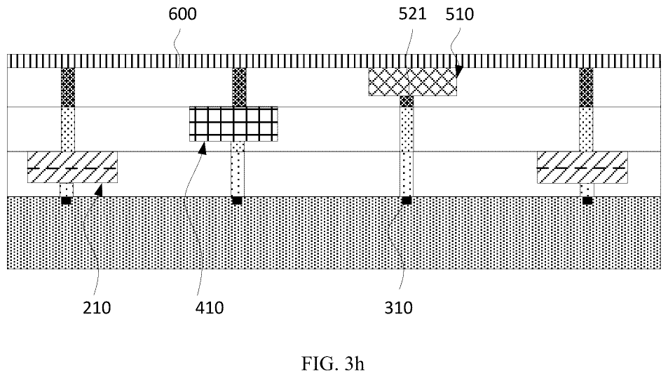

In some embodiments, the first filling structure 220 is provided between the first LED units 210, where the first filling structure 220 is at least located circumferentially around the first LED units 210. As shown in FIG. 2c, the first filling structure 220 may be disposed circumferentially around the first LED unit 210. Alternatively, as shown in FIG. 3a, the first filling structure 220 covers the first LED unit 210. Specifically, the first filling structure 220 is disposed circumferentially around the first LED unit 210 and covers a surface of the first doped semiconductor layer 211 of the first LED unit 210 that faces away from a side of the second doped semiconductor layer 213 of the first LED unit 210. The first filling structure 220 may be formed by employing at least one of processes such as deposition, coating and the like. The material of the first filling structure 220 may be selected from polyimide, wall-blocking adhesive, OC adhesive, SU8 photoresist, or benzocyclobutene (BCB). In some embodiments, the first filling structure 220 is positioned at least between the first LED units 210 in a case where the first LED units 210 are spaced apart from each other. The first filling structure 220 may be disposed between the first LED units 210. Alternatively, the first filling structure 220 may be disposed between the first LED units 210 and cover the first LED units 210. As seen in FIG. 2d, in some embodiments, the first filling structure 220 is provided with the first conductive column 221 passing through first filling structure 220. The first conductive column 221 may be formed by opening a first aperture passing through the first filling structure 22 and filling the first aperture with conductive material. The first conductive column 221 may be made of transparent conductive material. Specifically, the transparent electrically conductive material may be indium tin oxide, for example. Also, the first conductive column 221 may be made of metal material. The first conductive column 221 may be used for electrically connecting the first LED unit 210 and the contact 310. The first conductive column 221 may also be used for electrically connecting the LED unit which emits light of different color from that of the first LED unit 210 to the contact 310. For example, the second LED unit is electrically connected to the contact 310.

The first LED layer 200 includes the first filling structure 220. The first filling structure 220 facilitates the flatness of the first LED layer 200 and reduces the difficulty of bonding the first LED layer and the driving substrate 300. In addition, the first filling structure 220 serves to protect and stabilize the first LED unit, even when the first LED units 210 are spaced apart from each other. The first filling structure 220 helps to reduce the difficulty of bonding the first LED unit 210 with the driving substrate 300, as well as increase the stability of the first LED unit 210 after being bonded with the driving substrate 300, while to a certain extent, reducing the risk of the first LED unit 210 being stripped during the production process and improving the yield of the Micro-LED display chip.

Step S130: bonding the first LED layer 200 to the driving substrate 300, where the first LED unit 210 and the first conductive column 221 are electrically connected to the contact 310, respectively.

With reference to FIG. 2e, in some embodiments, the first LED unit 210 and the first conductive column 221 are electrically connected to the contacts 310, respectively. The first LED layer 200 may include the first conductive column 221 disposed between the first LED units 210. The first LED layer 200 may further include the first conductive column 221 in contact with the first doped semiconductor layer 211 of the first LED unit 210. The first LED unit 210 may be electrically connected to the contact 310 via the first conductive column 221. In some embodiments, the first filling structure 220 is only located circumferentially around the first LED unit 210. The first conductive column 221 may not be provided between the first LED units 210 and the first conductive column 221. The first LED units 210 may be electrically connected to the contacts 310 through the first doped semiconductor layer 211.

By adopting the process sequence of forming the first LED layer 200 including the first LED unit 210, the first filling structure 220, and the first conductive column 221 first, and then boding it with the driving substrate 300, the driving substrate 300 is better protected, thus improving the yield rate. Moreover, if defects occur in the first LED layer 200, only the first LED layer 200 needs to be repaired or discarded without affecting the driving substrate 300, thereby helping to reduce costs.

Step S140: disposing a second LED layer 400 on the first LED layer 200, where the second LED layer 400 includes multiple second LED units 410 and a second filling structure 420 disposed between the second LED units 410. The second LED units 410 are electrically connected to the first conductive column 221 directly below them, and the second LED units 410 emit light of different color from that of the first LED units 210.

With reference to FIG. 2c, FIG. 2b, and FIG. 2f, in some embodiments, the first LED epitaxial layer 200a is etched to form multiple first LED units 210. Each of the first LED units 210 includes the first doped semiconductor layer 211, the active layer 212, and the second doped semiconductor layer 213. In a case where the second doped semiconductor layers 213 of the adjacent first LED units 210 are interconnected, prior to the step of providing the second LED layer 400 on the first LED layer, a step of thinning the second doped semiconductor layer 213 of the first LED unit 210 to expose the top of the first conductive column 221 is further included. The multiple first LED units 210 after being thinned are spaced apart from each other. The thinning of the second doped semiconductor layer 213 of the first LED units 210 may be realized by etching, or by thinning various regions of the second doped semiconductor layer 213 simultaneously. Since the first filling structure 220 is in contact with the surface of the second doped semiconductor layer 213, the first conductive column 221 passes through the first filling structure 220. Therefore, in a case where the top of the first conductive column 221 is exposed, the second doped semiconductor layer 213 connecting the multiple first LED units 210 is interrupted, and the surface of the first conductive column 221 facing away from the first doped semiconductor layer 211 is exposed. The multiple first LED units 210 are spaced apart from each other, and the first LED units 210 are interspersed with the first filling structure 220.

By retaining part of the second doped semiconductor layer 213 and thinning the second doped semiconductor layer 213 after the first LED layer 200 is bonded to the driving substrate 300, the stability of the first LED units 210 may be improved and the first LED units 210 may be prevented from falling off during the bonding process. Moreover, by forming the multiple first LED units 210 spaced apart from each other after thinning, it is convenient for the second LED unit 410 to be electrically connected to the contact 310 and be independently driven.

In some embodiments, the first LED layer 200 is provided on the surface of the substrate 100, or the first LED epitaxial layer 200a is formed by growing on the substrate 100. Prior to the step of thinning the second doped semiconductor layer 213 of the first LED units 210, it may also include a step of removing the substrate 100. As a result of retaining part of the second doped semiconductor layer 213, the risk that part of the first LED units 210 will be removed at the same time during the removal process of the substrate 100 can be minimized, which, to some extent, improves the preparation yield.

In some embodiments, after forming the multiple first LED units 210 spaced apart from each other, it is possible to provide the conductive layer on the second doped semiconductor layer 213 of the first LED units 210. The conductive material of the conductive layer may be metallic material or indium tin oxide. The first LED unit 210 may be electrically connected to the second conductive column 421 via the conductive layer of the second doped semiconductor layer 213. The conductive layer on the second doped semiconductor layer 213 is not illustrated in FIG. 2f. In some embodiments, it is possible to provide the conductive layer on the surface of the first doped semiconductor layer and the second doped semiconductor layer of the LED unit, and the conductive layer is used for electrically connecting the LED unit to the corresponding contact or the corresponding conductive column. The LED unit may refer to a first LED unit, or a second LED unit, or a third LED unit.

With reference to FIG. 2g and FIG. 2h, in some embodiments, the step of disposing the second LED layer 400 on the first LED layer 200 includes: providing the second LED layer 400, where the second LED layer 400 includes multiple second LED units 410 and the second filling structure 420 disposed between the second LED units 410; and bonding the second LED layer 400 to the first LED layer 200, where the second LED units 410 is electrically connected to the contact 310 through the electrical connection with the first conductive column 221 directly below them.

In some embodiments, the second LED epitaxial layer 400a includes the first doped semiconductor layer, the active layer and the second doped semiconductor layer, as can be understood with reference to FIG. 2a. The first doped semiconductor layer, the active layer, and the second doped semiconductor layer are not shown in FIG. 2g. The active layer included in the second LED epitaxial layer 400a may be different from the active layer 212 included in the first LED epitaxial layer 200a, so as to realize that the second LED unit 410 emits light of different color from that of the first LED unit 210. The first doped semiconductor layer and the second doped semiconductor layer included in the second LED epitaxial layer 400a may be the same as or different from the first doped semiconductor layer 211 and the second doped semiconductor layer 213 included in the first LED epitaxial layer 200a.

In some embodiments, the second LED unit 410 is formed by processing the second LED epitaxial layer 400a including the first doped semiconductor layer, the active layer, and the second doped semiconductor layer, which may be referred to the first LED unit 210. The second LED units 410 formed after the processing of the second LED epitaxial layer 400a may be spaced apart from each other or may be connected to each other through the second doped semiconductor layer. Two second LED units 410 are illustrated in FIG. 2h.

In some embodiments, the second filling structure 420 may be referred to the first filling structure 220. With reference to FIG. 2i, in some embodiments, the second filling structure 420 is at least located circumferentially around the second LED unit 410. Specifically, the second filling structure 420 may be disposed circumferentially around the second LED unit 410. Alternatively, the second filling structure 420 covers the second LED unit 410.

In some embodiments, it is possible to form a conductive layer on the surface of the first doped semiconductor layer of the second LED unit 410. The conductive material of the conductive layer may be metallic material, such as indium tin oxide. The second LED unit 210 may be electrically connected to the first conductive column 221 via the conductive layer on the first doped semiconductor layer of the second LED unit 210. The conductive layer on the surface of the first doped semiconductor layer is not illustrated in FIG. 2j and FIG. 2k.

With reference to FIG. 2j, in some embodiments, the second LED layer 400 is further provided with a second conductive column 421 passing through the second filling structure 420, and the number and position of the second conductive column 421 may be determined according to the first LED unit 210. The second LED layer 400 may include a second conductive column 421 located directly above the first LED unit 210. The second conductive column 421 may be used to electrically connect the first LED unit 210 to the common electrode 600.

With reference to FIG. 2k, in some embodiments, the second LED unit 410 is electrically connected to the contact 310 through the electrical connection with the first conductive column 221 directly below it. In some embodiments, the second LED unit 410 is spaced apart from the first LED unit 210. A positive projection of the first conductive column 221 directly below the second LED unit 410 on the second LED unit 410 is located within the first doped semiconductor layer of the second LED unit 410. The first doped semiconductor layer of the second LED unit 410 is electrically connected to the first conductive column 221 disposed directly below the second LED unit 410, thereby realizing the electrical connection between the second LED unit 410 and the contact 310. In some embodiments, the electrical connection between the first doped semiconductor layer of the second LED unit 410 and the first conductive column 221 can be realized by direct contact.

In some embodiments, the second LED layer 400 is further provided with a second conductive column 421 passing through the second filling structure 420, and the second conductive column 421 located directly above the first LED unit 210 is electrically connected to the second doped semiconductor layer 213 of the first LED unit 210, respectively, so as to realize the electrical connection between the first LED unit 210 and the common electrode 600. The second LED unit 410 emits light of different color from that of the first LED unit 210. In this way, a multi-color display can be realized even without a wavelength conversion structure, reducing the difficulty of fabrication and improving the efficiency of fabrication.

With reference to FIG. 21, in some embodiments, the second LED epitaxial layer 400a is disposed on the substrate 100. After the step of bonding the second LED layer 400 with the first LED layer 200, a step of removing the substrate 100 may be further included. In a case where the second doped semiconductor layers of the second LED units 410 are interconnected, a step of thinning the second LED layer 400 to expose the top of the second conductive column 421 may be further included. Specific reference may be made to the above-described content of thinning the second doped semiconductor layer 213 of the first LED unit 210 to expose the top of the first conductive column 221, which will not be described here again.

In some embodiments, disposing the second LED layer 400 on the first LED layer 200 may be achieved by bonding the second LED unit 410 with the first LED layer 200 and providing the second filling structure 420 between the second LED units 410. It is also possible to provide the second conductive column 421 passing through the second filling structure 420.

The method for manufacturing the Micro-LED display chip provided according to the embodiment of the present disclosure enables a multi-color display without a wavelength conversion layer by providing the second LED unit 410 and the first LED unit 210 which emit light of different colors from each other. Moreover, due to the characteristics of the small size of the LED unit of the Micro-LED display chip, the wavelength conversion layer is difficult to prepare and has the defect of low conversion efficiency. Therefore, it is beneficial to reduce the preparation difficulty and improve the light-emitting efficiency by providing the second LED unit 410 and the first LED unit 210 which emit light of different colors from each other. By adopting the process sequence of forming the first LED layer 200 including the first LED unit 210, the first filling structure 220, and the first conductive column 221 first, and then boding it with the driving substrate 300, the driving substrate 300 is better protected, thus improving the yield rate and reducing the cost.

In some embodiments, the second conductive column 421 and the second doped semiconductor layer of the second LED unit 410 are electrically connected to the common electrode 600 respectively, so that the first LED unit 210 and the second LED unit 410 may be driven separately and independently.

With reference to FIG. 2m, in some embodiments, the second conductive column 421 and the second doped semiconductor layer 213 of the second LED unit 410 are electrically connected to the common electrode 600. The electrical connection may be achieved by direct contact. It is also possible that other conductive structures are additionally provided to realize the electrical connection.

In some embodiments, the common electrode 600 is provided on the surface of the second LED layer 400 facing away from the driving substrate 300. The second conductive column 421 and the second doped semiconductor layer 213 of the second LED unit 410 are electrically connected to the common electrode 600 respectively, and the second LED unit 410 and the first LED unit 210 may be driven separately and independently. The common electrode 600 is conducive to reducing the difficulty of driving.

In some embodiments, multiple common electrodes 600 are provided. The second conductive column 421 and the second doped semiconductor layer 213 of the second LED unit 410 are electrically connected to the common electrodes 600 respectively. Each of the second LED units 410 and each of the first LED units 210 may be provided with corresponding common electrodes 600, respectively.

With reference to FIG. 3a, FIG. 3b, and FIG. 3c, in some embodiments, the first LED unit 210 is electrically connected to the contact 310 of the driving substrate 300 by means of the corresponding first conductive column 221. Specifically, in the first LED layer 200, the first filling structure 220 covers the first LED unit 210. Accordingly, the step of disposing the first conductive column 221 passing through the first filling structure 220 includes disposing the first conductive column 221 on the first LED unit 210, where the first LED unit 210 is electrically connected to the contact 310 through the corresponding first conductive column 221.

In some embodiments, the first filling structure 220 covers the first doped semiconductor layer 211 of the first LED unit 210. The first conductive column 221 connecting the first LED unit 210 may be formed by providing a through hole passing through the first filling structure 220 in the first doped semiconductor layer 211 and filling the through hole with conductive material. Accordingly, the first LED layer 200 is electrically bonded to the driving substrate 300, the first conductive column 221 connected to the first LED unit 210 realizes the electrical connection between the first LED unit 210 and the contact 310, and the first LED unit 210 is electrically connected to the contact 310 through an indirect connection.

By providing the first filling structure 220 covering the first LED unit 210, it is conducive to reducing the difficulty of preparing the first filling structure 220, and by providing the first conductive column 221, it is conducive to improving the strength of the bonding of the first LED layer 200 and the driving substrate 300, and the separation of the first LED layer and the driving substrate 300 during the fabrication process can be avoided, which improves the yield rate.

With reference to FIG. 3e, in some embodiments, the second filling structure 420 covers the second LED unit 410. The second conductive column 421 connecting the second LED unit 410 and the first conductive column 221 may be formed by providing a through hole in the second filling structure 420 covering the first doped semiconductor layer of the second LED unit 410 and filing the through hole with the conductive material. Accordingly, the second LED unit 410 is electrically connected to the contact 310 via the first conductive column 221 and the second conductive column 421. The second LED unit 410 is electrically connected to the first conductive column 221 through an indirect connection.

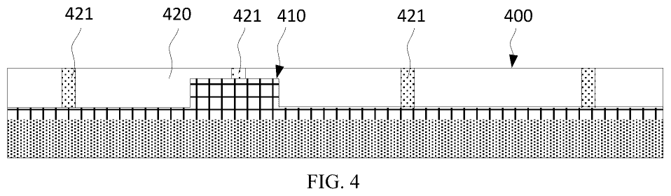

With reference to FIG. 3b, FIG. 3d, FIG. 3e, and FIG. 4, the second filling structure 420 is further provided with the second conductive column 421 passing through the second filling structure 420, where the second conductive column 421 is electrically connected to the first conductive column 221 directly below it.

With reference to FIG. 3f, in some embodiments, the second LED epitaxial layer 400a is provided on the substrate 100. After the second LED layer 400 is bonded to the first LED layer 200, it may further include a step of removing the substrate 100. In a case where the second doped semiconductor layers of the second LED units 410 are interconnected, it may further include a step of thinning the second LED layer 400 to expose the top of the second conductive column 421. Specific reference may be made to the above-described content of thinning the second doped semiconductor layer 213 of the first LED unit 210 to expose the top of the first conductive column 221, which will not be described here again.

In some embodiments, it is possible to form the conductive layer on the surface of the second doped semiconductor layer of the second LED unit 410. The conductive material of the conductive layer may be metallic material or indium tin oxide. The conductive layer on the second doped semiconductor layer of the second LED unit 210 may be used for electrical connection between the second LED unit 210 and the third conductive column 521.

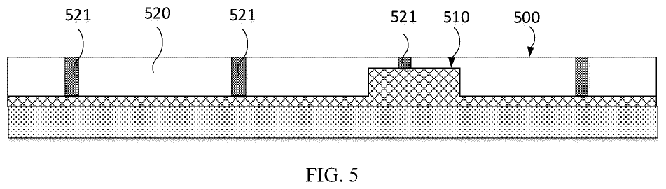

With reference to FIG. 3g and FIG. 5, in some embodiments, the method for manufacturing the micro-LED display chip may further includes disposing a third LED layer 500 on the second LED layer 400. The third LED layer 500 includes multiple third LED units 510 and a third filling structure 520 positioned between the third LED units 510. The third LED units 510 are electrically connected to the contact 310 by means of the first conductive column 221 and the second conductive column 421 directly below thereof. The third LED units 510, the second LED units 410, and the first LED units 210 emit light of different colors. By providing the second conductive column 421 electrically connected to the first conductive column 221, and the third LED unit emit light of different color from both the first LED unit and the second LED unit, the color display range of the Micro-LED display chip can be improved, and the application scope of Micro-LED display chip can be expanded.

In some embodiments, the third LED unit 510 is formed by processing the third epitaxial layer including the first doped semiconductor layer, the active layer, and the second doped semiconductor layer. The third LED unit 510 includes the first doped semiconductor layer, the active layer, and the second doped semiconductor layer arranged in a stacked manner. Specific reference may be made to the manufacturing of the first LED unit 210, which will not be repeated herein.

In some embodiments, a conductive layer may be formed on the surface of the first doped semiconductor layer of the third LED unit 510. The conductive material of the conductive layer may be metallic material or indium tin oxide. In a case where the third conductive column 521 is not provided directly below the third LED unit 510, the third LED unit 510 may be electrically connected to the second conductive column 421 via the conductive layer on the first doped semiconductor layer of the third LED unit 510.

With reference to FIG. 3g and FIG. 5, in some embodiments, the third filling structure 520 covers the third LED unit 510. The third conductive column 521 electrically connecting the third LED unit 510 may be formed by providing a through hole in the first doped semiconductor layer passing through the third filling structure 520 and filling the through hole with a conductive material. Accordingly, the third LED unit 510 is electrically connected to the contact 310 by means of the first conductive column 221, the second conductive column 421, and the third conductive column 521 directly below thereof. The third LED unit 510 is electrically connected to the second conductive column 421 through an indirect connection.

In some embodiments, the conductive layer may be formed on the surface of the first doped semiconductor layer of the third LED unit 510. The conductive material of the conductive layer may be metallic material or indium tin oxide. The third LED unit 510 may be electrically connected to the third conductive column 521 via the conductive layer on the first doped semiconductor layer of the third LED unit 510.

In some embodiments, the third LED unit 510 emits light of different color from that of the second LED unit 410 and the first LED unit 210. The third LED unit 510, the second LED unit 410, and the first LED unit 210 may emit light of red, blue, and green, respectively. By providing multiple LED units that emit light of different color, the range of display colors of the Micro-LED display chip may be expanded, thereby increasing the application scope of the Micro-LED display chip.

With reference to FIG. 3h, in some embodiments, the third filling structure 520 is further provided with a third conductive column 521 passing through the third filling structure 520. The method for manufacturing the micro-LED display chip further includes providing a common electrode 600 on the third LED layer. The first LED unit 210 is connected to the common electrode 600 through the second conductive column 421 and the third conductive column 521 located directly above it, the second LED unit 410 is electrically connected to the common electrode 600 through the third conductive column 521 located directly above it, and the third LED unit 510 is electrically connected to the common electrode 600. The third LED unit 510 may be electrically connected to the common electrode 600 through the second doped semiconductor layer. The third LED unit 510, the second LED unit 410 and the first LED unit 210 may be driven separately and independently. The common electrode 600 may be made of transparent conductive material. The common electrode 600 may be formed by a vapor deposition process. By providing the common electrode 600 on the surface of the third LED layer 500 facing away from the driving substrate 300, it is beneficial to improve the flatness of the common electrode 600, improve the stability of the electrical connection, and thereby improve the yield rate.

A Micro-LED display chip is provided according to an embodiment of the present disclosure. The Micro-LED display chip may include: a driving substrate 300, where the driving substrate 300 includes a driving circuit and a contact 310 electrically connected to the driving circuit; a first LED layer 200 disposed on the driving substrate 300, where the first LED layer 200 includes multiple first LED units 210, a first filling structure 220 disposed between the first LED units 210 and a first conductive column 221 passing through the first filling structure 220, and the first LED unit 210 and the first conductive column 221 are electrically connected to the contact 310 respectively; a second LED layer 400 arranged on the first LED layer 200, where the second LED layer 400 includes multiple second LED units 410 and a second filling structure 420 located between the second LED units 410, the second LED units 410 are electrically connected to the first conductive column 221 directly below it, and the second LED units 410 emit light of different color from that of the first LED units 210.

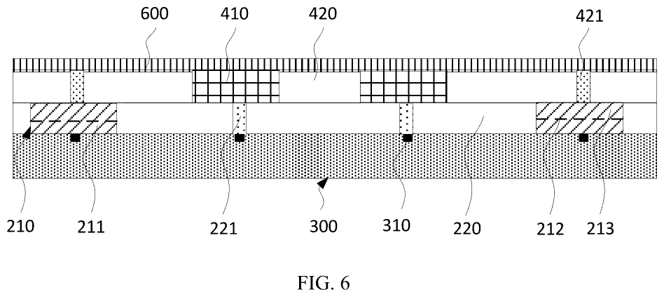

With reference to FIG. 6, in some embodiments, the first LED layer 200 includes multiple first LED units 210 spaced apart from each other. The first LED unit 210 includes a first doped semiconductor layer 211, an active layer 212, and a second doped semiconductor layer 213. Accordingly, the first doped semiconductor layer 211, the active layer 212, and the second doped semiconductor layer 213 of the multiple first LED units 210 are spaced apart from each other. The first doped semiconductor layer 211, the active layer 212, and the second doped semiconductor layer 213 are disposed in a stacked manner, and the active layer 212 is disposed between the first doped semiconductor layer 211 and the second doped semiconductor layer 213, and thus the second doped semiconductor layer 213 is disposed on a side of the first doped semiconductor layer 211 that faces away from the driving substrate 300. In some embodiments, for the first conductive column 221 located directly below the second LED unit 410, a positive projection of the first conductive column 221 on the second LED unit 410 is located within the first doped semiconductor layer of the second LED unit 410. The first conductive column 221 directly below the second LED unit 410 is connected to the first doped semiconductor layer of the second LED unit 410, and the second LED unit 410 is electrically connected to the contact 310 via the first conductive column 221.

In some embodiments, the first LED unit 210 is electrically connected to the contact 310 of the driving substrate 300. With reference to FIG. 6, there is no first conductive column 221 being provided between the first LED unit 210 and the driving substrate 300.

With reference to FIG. 6 and FIG. 2c, in some embodiments, the first LED layer 200 includes a first filling structure 220 disposed between the first LED units 210. The first filling structure 220 is used to enable the first LED layer 200 to have a first flattened surface. The first LED units 210 are spaced apart from each other, and a height difference is formed between the first LED units 210. The first filling structure 220 is disposed at least between the multiple first LED units 210 circumferentially around the first LED units 210, reducing or eliminating the height difference between the first LED units 210, improving the overall flatness of the Micro-LED display chip, and thereby improving the stability of the structure of the Micro-LED display chip.

With reference to FIG. 6, in some embodiments, the first filling structure 220 is disposed circumferentially around the first LED unit 210. The first filling structure 220 being disposed circumferentially around the first LED unit 210 may mean that the first filling structure 220 is disposed between the first LED units 210, surrounding the sides of the first LED unit 210.

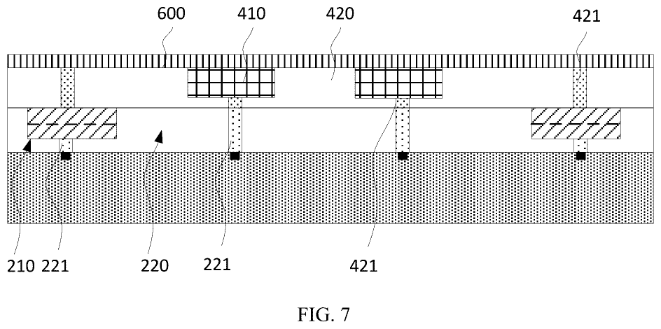

With reference to FIG. 7, in some embodiments, the first LED unit 210 is embedded in the first filling structure 220. Accordingly, the first filling structure 220 is disposed circumferentially around the first LED unit 210 and covers a surface of the first doped semiconductor layer 211 of the first LED unit 210 close to the substrate 300. The structure of the first LED unit 210 being embedded in the first filling structure 220 is advantageous to reduce the difficulty of preparing the first filling structure 220, thereby improving the preparation efficiency.

With reference to FIG. 7, in some embodiments, in a case where the first LED unit 210 is embedded in the first filling structure 220, a first conductive column 221 passing through the first filling structure 220 is further provided directly below the first LED unit 210, and the first conductive column 221 is electrically connected to the contacts 310 and the first doped semiconductor layer 211 of the first LED unit 210.

In some embodiments, the first conductive column 221 directly below the first LED unit 210 is in contact with a surface of the first doped semiconductor layer 211 of the first LED unit 210 facing back from the second doped semiconductor layer 213 of the first LED unit 210.

With reference to FIG. 6 or FIG. 7, in some embodiments, the first filling structure 220 is provided with a first conductive column 221 passing through the first filling structure 220. The first conductive column 221 is spaced apart from the first LED unit 210 for electrically connecting to the second LED unit 410.

In some embodiments, the second LED layer 400 is provided on a surface of the first LED layer 200 facing away from the driving substrate 300, and at least the second filling structure 420 in the second LED layer is in contact with the first LED layer 200, or the second filling structure 420 and the first doped semiconductor layer 211 of the first LED unit 210 are in contact with the first LED layer 200.

With reference to FIG. 6, in some embodiments, the second filling structure 420 is disposed circumferentially around the second LED unit 410. The second filling structure 420 being disposed circumferentially around the second LED unit 410 may refer to that the second filling structure 420 is disposed between the second LED units 410, surrounding the sides of the second LED unit 410.

With reference to FIG. 7, in some embodiments, the second LED unit 410 is embedded in the second filling structure 420. Specifically, the second filling structure 420 is disposed circumferentially around the second LED unit 410 and covers a surface of the second LED unit 410 close to the first LED unit 210. It is favorable to reduce the difficulty of preparing the second filling structure 420, thereby improving the preparation efficiency.

With reference to FIG. 7, in some embodiments, in a case where the second LED unit 410 is embedded in the second filling structure 420, a second conductive column 421 passing through the second filling structure 420 is further provided directly below the second filling structure 420, and the second conductive column 421 is electrically connected to the first conductive column 221 and the first doped semiconductor layer of the second LED unit 410.

In some embodiments, the second conductive column 421 directly below the second filling structure 420 is in contact with a surface of the first doped semiconductor layer of the second LED unit 410 close to the first LED unit 210.

In some embodiments, the second filling structure 420 is provided with a second conductive column 421 passing through the second filling structure 420. The second conductive column 421 is spaced apart from the second LED unit 410 for electrically connecting to the first LED unit 210.

In some embodiments, the second LED unit 410 emits light of different color from that of the first LED unit 210. The first LED unit 210 and the first conductive column 221 are electrically connected to the contact 310, and the second LED unit 410 is electrically connected to the first conductive column 221 directly below it. The first LED unit 210 and the second LED unit 410 may be driven separately and independently, realizing a multi-color display of the Micro-LED display chip, thereby increasing the application scope of the Micro-LED display chip. With respect to the multiple second LED units 410, reference may be made to the multiple first LED units 210, and will not be repeated herein.

The Micro-LED display chip provided according to the embodiment of the present disclosure may achieve multi-color display without a wavelength conversion layer, since the first LED unit 210 and the second LED unit 410 emitting light of different color are provided in the first LED layer 200 and the second LED layer 400, respectively. Furthermore, due to the small size of the LED unit of the Micro-LED display chip, preparing the wavelength conversion layer is challenging and suffers from low conversion efficiency. Therefore, by providing the second LED unit 410 and the first LED unit 210 emitting light of different color, it is conducive to reducing the difficulty of preparation and improving the light-emitting efficiency, and also improving the yield rate. Additionally, the providing of the first filling structure 220 and the second filling structure 420 not only protects the first LED unit 210 and the second LED unit 410, but also enhances the flatness between different film layers, thereby improving the structure stability of the Micro-LED display chip.

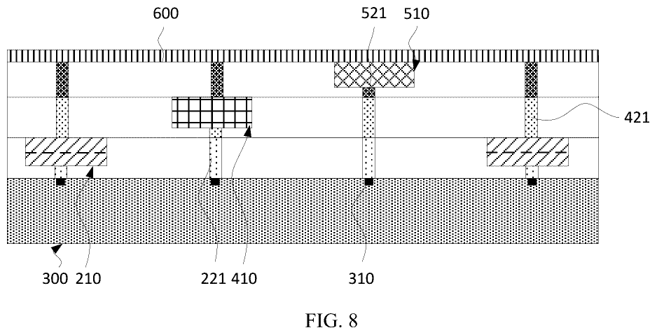

With reference to FIG. 8, in some embodiments, the second filling structure 420 is further provided with a second conductive column 421 passing through the second filling structure 420. The Micro-LED display chip further includes a third LED layer 500 provided on the second LED layer 400. The third LED layer 500 includes multiple third LED units 510 and a third filling structure 510 located between the third LED units 510. The third LED units 510 are electrically connected to the contact 310 by means of the first conductive column 221 and the second conductive column 421 located directly below thereof. The third LED units 510, the second LED units 410, and the first LED units 210 emit light of different color from each other.

With reference to FIG. 8, in some embodiments, the material of the first conductive column 221, the second conductive column 421, and the third conductive column 521 may be the same. The material may be transparent conductive material, metal material, or the like.

In some embodiments, the third LED layer 500 includes multiple third LED units 510 spaced apart from each other. The third LED unit 510 may include a first doped semiconductor layer, an active layer, and a second doped semiconductor layer. Accordingly, the first doped semiconductor layer, the active layer, and the second doped semiconductor layer of the multiple third LED units 510 are spaced apart from each other. It can be understood that the first doped semiconductor layer, the active layer and the second doped semiconductor layer are arranged in a stacked manner, and the active layer is disposed between the first doped semiconductor layer and the second doped semiconductor layer. The second doped semiconductor layer of the third LED unit 510 is disposed at a side of the first doped semiconductor layer of the third LED unit 510 facing away from the driving substrate 300. The first doped semiconductor layer of the third LED unit 510 is electrically connected to the second conductive column 421 and the first conductive column 221 located directly below it, so that the electrical connection between the third LED unit 510 and the contact 310 is realized.

In some embodiments, the third LED layer 500 further includes a third filling structure 520. The third filling structure 520 is used to enable the multiple third LED units 510 to have a third flattened surface in the third LED layer 500. The third filling structure 520 may be disposed circumferentially around the third LED units 510. The third filling structure 520 being disposed circumferentially around the third LED units 510 may mean that the third filling structure 520 is disposed between the third LED units 510, surrounding the sides of the third LED units 510.

In some embodiments, the third LED unit 510 is embedded in the third filling structure 520. Specifically, the third filling structure 520 is disposed circumferentially around the first LED unit 210 and covers a surface of the first doped semiconductor layer of the third LED unit 510 close to the second LED unit 410. It is advantageous to reduce the difficulty of preparing the third filling structure 520, thereby improving the efficiency of the preparation.

With reference to FIG. 8, in some embodiments, in a case where the third LED unit 510 is embedded in the third filling structure 520, a third conductive column 521 passing through the third filling structure 520 is further provided directly below the third LED unit 510, and the third conductive column 521 is electrically connected to the first doped semiconductor of the third LED unit 510. The third LED unit 510 is electrically connected to the contact 310 through the third conductive column 521, the second conductive column 421, and the first conductive column 221 located directly below it.

In some embodiments, the third conductive column 521 disposed directly below the third LED unit 510 is in contact with a surface of the first doped semiconductor layer close to the second LED unit 410.

In some embodiments, the third filling structure 520 is further provided with a third conductive column 521 passing through the third filling structure 520. The third filling structure 520 may be provided with the third conductive column 521 disposed between the third LED units 510, which may be used for electrically connecting the second LED unit 410 or the first LED unit 210 to the common electrode. The third filling structure 520 may be provided with the third conductive column 521 disposed directly below the third LED unit 510, which may be used for electrically connecting the third LED unit 510 to the contact 310.

In some embodiments, the Micro-LED display chip further includes the common electrode 600 provided on the third LED layer 500. The first LED unit 210 is electrically connected to the common electrode 600 via the second conductive column 421 and the third conductive column 521 located directly above it, the second LED unit 410 is electrically connected to the common electrode 600 via the third conductive column 521 located directly above it, and the third LED unit 510 is electrically connected to the common electrode 600.

In some embodiments, the first LED unit 210, the second LED unit 410, and the third LED unit 510 may emit light of different color selected from red, green, and blue, respectively. The first LED unit 210, the second LED unit 410, and the third LED unit 510 emit light of different color from each other. This facilitates the realization of a full color display. In some embodiments, the first LED unit 210, the second LED unit 410, and the third LED unit 510 may emit light of different color selected from any color such as purple, yellow, or the like, so as to improve the application scope of the Micro-LED display chip.

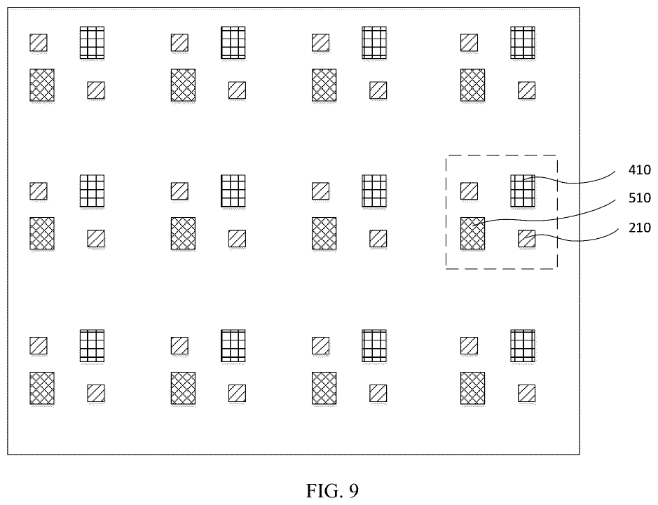

In some embodiments, the Micro-LED display chip is divided into multiple pixel units arranged in an array. The pixel units include at least one first LED units 210, at least one second LED units 410, and at least one third LED units 510, where the number of the first LED units 210, the number of the second LED units 410 and the number of the third LED units 510 in the pixel unit are not identical. With reference to FIG. 9, the pixel unit is illustrated in a dashed box in FIG. 9, where the pixel unit includes two first LED units 210, one second LED unit 410, and one third LED unit 510.

In some embodiments, the first LED unit 210, the second LED unit 410, and the third LED unit 510 may emit light of red, green, and blue, respectively. In one pixel unit, the number of the second LED units 410 may be greater than the number of the first LED units 210, and the number of the second LED units 410 may be greater than the third LED units 510. The pixel may be formed by the number of the first LED units, the second LED units, and the third LED units, which provides various methods for forming the pixel.

A display panel is provided according to an embodiment of the present disclosure, including the Micro-LED display chip as described in any one of the above embodiments.

In the present embodiment, the display panel includes the Micro-LED display chip described in any one of the above embodiments. Since the display color range of the Micro-LED display chip becomes larger, the display color range of the display panel is thereby increased, and the application scope of the display panel is expanded.

A display device is provided according to an embodiment of the present disclosure, including the Micro-LED display chip as described in any one of the above embodiments.

In the present embodiment, the display device includes the Micro-LED display chip described in any one of the above embodiments. Since the display color range of the Micro-LED display chip becomes larger, the display color range of the display device is thereby increased, and the application scope of the display device is expanded.

The embodiments in the present disclosure focus on emphasizing the parts that are different from other embodiments, and each embodiment can be interpreted against each other. Any combination of the embodiments in this specification by a person skilled in the art based on general technical knowledge is covered by the scope of the present disclosure.

The technical features of the above embodiments can be combined at will. For conciseness of description, not all of the possible combinations of the technical features of the above embodiments have been described herein. However, the combinations of the technical features should be considered as falling within the scope of the present disclosure as long as there is no contradiction.

The above description is only a part of the embodiments in the present disclosure, and is not intended to limit the present disclosure, and any modifications, equivalent substitutions, etc. made within the spirit and principles of the present disclosure shall be included in the scope of the present disclosure.

What is claimed is:

1. A method for manufacturing a Micro-LED display chip, comprising:
providing a driving substrate, wherein the driving substrate comprises a driving circuit and a contact electrically connected to the driving circuit;
providing a first LED layer, wherein the first LED layer comprises a plurality of first LED units, a first filling structure located between the first LED units, and a first conductive column passing through the first filling structure;
bonding the first LED layer to the driving substrate, wherein the first LED units and the first conductive column are electrically connected to the contact respectively; and
disposing a second LED layer on the first LED layer, wherein the second LED layer comprises a plurality of second LED units and a second filling structure located between the second LED units, the second LED units are electrically connected to the first conductive column directly below them, and the second LED units emit light of a different color from that of the first LED units.

2. The method for manufacturing the Micro-LED display chip according to claim 1, wherein
the step of forming the first LED unit comprises: providing a first LED epitaxial layer comprising a doped semiconductor layer and an active layer, and etching the first LED epitaxial layer to form the plurality of first LED units;
the step of forming the second LED unit comprises: providing a second LED epitaxial layer comprising a doped semiconductor layer and an active layer, and etching the second LED epitaxial layer to form the plurality of second LED units;
wherein the active layer of the second LED epitaxial layer is different from that of the first LED epitaxial layer, so as to realize that the second LED units emit light of a different color from that of the first LED units.

3. The method for manufacturing the Micro-LED display chip according to claim 1, wherein the step of providing the first LED layer comprises:
providing a first LED epitaxial layer;
etching the first LED epitaxial layer to form the plurality of first LED units, wherein each of the first LED units comprises a first doped semiconductor layer, an active layer and a second doped semiconductor layer, and the second doped semiconductor layers of the adjacent first LED units are interconnected;
providing the first filling structure between the first LED units; and
providing the first conductive column passing through the first filling structure.

4. The method for manufacturing the Micro-LED display chip according to claim 3, wherein before the step of disposing the second LED layer on the first LED layer, it further comprises:
thinning the second doped semiconductor layer of the first LED unit until a top end of the first conductive column is exposed, wherein the plurality of first LED units after thinning are spaced apart from each other.

5. The method for manufacturing the Micro-LED display chip according to claim 1, wherein the step of providing the first LED layer comprises:
providing a first LED epitaxial layer;
etching the first LED epitaxial layer to form the plurality of first LED units spaced from each other, wherein each of the first LED units comprises a first doped semiconductor layer, an active layer and a second doped semiconductor layer;
providing the first filling structure between the first LED units; and
providing the first conductive column passing through the first filling structure.

6. The method for manufacturing the Micro-LED display chip according to claim 1, wherein in the first LED layer, the first filling structure covers the first LED unit; and
the step of providing the first conductive column passing through the first filling structure correspondingly comprises:
providing the first conductive column on the first LED unit, wherein the first LED unit is electrically connected to the contact through the corresponding first conductive column.

7. The method for manufacturing the Micro-LED display chip according to claim 6, wherein the first filling structure covering the first LED unit comprises:
the first filling structure is located circumferentially around the first LED unit and covers a surface of the first doped semiconductor layer of the first filling structure that faces away from the second doped semiconductor layer of the first LED unit; or
the first filling structure is located between the plurality of first LED units spaced apart from each other and covers the first LED units.

8. The method for manufacturing the Micro-LED display chip according to claim 1, wherein the step of arranging a second LED layer on the first LED layer comprises:
providing a second LED layer, wherein the second LED layer comprises a plurality of second LED units and a second filling structure positioned between the second LED units; and
bonding the second LED layer with the first LED layer, wherein the second LED unit is electrically connected to the contact through the electrical connection with the first conductive column directly below it.

9. The method for manufacturing the Micro-LED display chip according to claim 1, wherein the second filling structure is further provided with a second conductive column passing through the second filling structure, and the second conductive column is electrically connected to the first conductive column directly below it, and the method for manufacturing the Micro-LED display chip further comprise the following step:
providing a third LED layer on the second LED layer, wherein the third LED layer comprises a plurality of third LED units and a third filling structure located between the third LED units, the third LED unit is electrically connected to the contact through the first conductive column and the second conductive column directly below it, and the third LED unit, the second LED unit and the first LED unit emit light of different color from each other.

10. The method for manufacturing the Micro-LED display chip according to claim 9, wherein the third filling structure is further provided with a third conductive column passing through the third filling structure, and the method for manufacturing the Micro-LED display chip further comprise the following step:
providing a common electrode on the third LED layer, wherein the first LED unit is electrically connected to the common electrode through the second conductive column and the third conductive column directly above thereof, the second LED unit is electrically connected to the common electrode through the third conductive column directly above thereof, and the third LED unit is electrically connected to the common electrode.

11. A Micro-LED display chip, comprising:
a driving substrate, wherein the driving substrate comprises a driving circuit and a contact electrically connected to the driving circuit;
a first LED layer disposed on the driving substrate, wherein the first LED layer comprises a plurality of first LED units, a first filling structure between the first LED units and a first conductive column passing through the first filling structure, and the first LED units and the first conductive column are electrically connected to the contacts respectively; and
a second LED layer disposed on the first LED layer, wherein the second LED layer comprises a plurality of second LED units and a second filling structure located between the second LED units, and the second LED units are electrically connected to the first conductive column directly below them, and the second LED units emit light of a different color from that of the first LED units.

12. The Micro-LED display chip according to claim 11, wherein
the first LED unit is formed by etching a first LED epitaxial layer, which comprises a doped semiconductor layer and an active layer;
the second LED unit is formed by etching a second LED epitaxial layer, which includes a doped semiconductor layer and an active layer;
wherein the active layer of the second LED epitaxial layer is different from that of the first LED epitaxial layer, so as to realize that the second LED unit emits light of different color from that of the first LED unit.

13. The Micro-LED display chip according to claim 11, wherein
the plurality of first LED units are adjacent to each other, or the plurality of first LED units are spaced apart from each other; and
the plurality of second LED units are adjacent to each other, or the plurality of second LED units are spaced apart from each other.

14. The Micro-LED display chip according to claim 11, wherein
the first conductive column is arranged on the first LED unit, and the first LED unit is electrically connected to the contact through the corresponding first conductive column.

15. The Micro-LED display chip according to claim 11, wherein in the first LED layer, the first filling structure covers the first LED unit, and wherein
the first filling structure is located circumferentially around the first LED unit and covers a surface of the first doped semiconductor layer of the first filling structure facing away from the second doped semiconductor layer of the first LED unit; or
the first filling structure is located between the plurality of first LED units spaced apart from each other and covers the first LED units.

16. The Micro-LED display chip according to claim 11, wherein the second filling structure is further provided with a second conductive column passing through the second filling structure; and
the Micro-LED display chip further comprise a third LED layer arrange on the second LED layer, wherein the third LED layer comprises a plurality of third LED units and a third filling structure located between the third LED units, the third LED unit is electrically connected to the contact through the first conductive column and the second conductive column directly below it, and the third LED unit, the second LED unit and the first LED unit emit light of different color from each other.

17. The Micro-LED display chip according to claim 16, wherein the third filling structure is further provided with a third conductive column passing through the third filling structure, and the Micro-LED display chip further comprises a common electrode arranged on the third LED layer, wherein the first LED unit is electrically connected to the common electrode through the second conductive column and the third conductive column directly above it, the second LED unit is electrically connected to the common electrode through the third conductive column directly above it, and the third LED unit is electrically connected to the common electrode.

18. The Micro-LED display chip according to claim 16, wherein the Micro-LED display chip is divided into a plurality of pixel units arranged in an array, and the pixel unit comprises at least one first LED units, at least one second LED units and at least one third LED units, wherein the number of the first LED units, the number of the second LED units and the number of the third LED units in the pixel unit are not exactly the same.

19. The Micro-LED display chip according to claim 16, wherein the first LED unit, the second LED unit and the third LED unit emit light of colors selected from red, green and blue, respectively.

20. The Micro-LED display chip according to claim 16, wherein the first LED unit is embedded in the first filling structure, and the first LED unit is electrically connected to the contact through the first conductive column directly below it; and/or
the second LED unit is embedded in the second filling structure, and the second LED unit is electrically connected to the contact through the second conductive column and the first conductive column located directly below it.
